(19) United States
(12) Patent Application Publication
(10) Pub. No.: US 2025/0204163 A1
(43) Pub. Date: Jun. 19, 2025

(54) DISPLAY SUBSTRATE, PREPARATION METHOD THEREFOR, AND DISPLAY APPARATUS

(71) Applicant: BOE Technology Group Co., Ltd., Beijing (CN)

(72) Inventors: Qian JIA, Beijing (CN); Tingting ZHOU, Beijing (CN); Yingtao WANG, Beijing (CN); Jaegeon YOU, Beijing (CN); Haokun LI, Beijing (CN); Xuefei SUN, Beijing (CN)

(21) Appl. No.: 18/846,672

(22) PCT Filed: Jan. 18, 2024
(86) PCT No.: PCT/CN2024/072963

§ 371 Date: Sep. 13, 2024

(30) Foreign Application Priority Data
Feb. 28, 2023 (CN) 202310215173.4

(51) Int. Cl. H10K 59/122; H10K 59/12; H10K 59/80

(52) U.S. Cl. CPC H10K 59/122; H10K 59/1201; H10K 59/80515

(57) ABSTRACT

A display substrate includes a base substrate, and a pixel define layer and a first electrode which are disposed on the base substrate. The pixel define layer comprises an opening, a side wall of the first electrode is in a step shape, and the opening is exposed out of the first electrode. The pixel define layer covers at least part of a side wall of the first electrode. The orthographic projection, on the base substrate, of the surface of the first electrode away from the base substrate falls within the orthographic projection of the opening on the base substrate.

### CROSS-REFERENCE TO RELATED APPLICATIONS

This application is a national stage application of PCT Application No. PCT/CN2024/072963, which is filed on Jan. 18, 2024 and claims priority to Chinese Patent Application No. 202310215173.4 filed to the CNIPA on Feb. 28, 2023 and entitled “Display Substrate, Preparation Method Therefor, and Display Apparatus”, contents of which should be construed as being incorporated into the present application by reference.

### TECHNICAL FIELD

The present disclosure relate to, but are not limited to, the field of display technologies, and particularly, to a display substrate and a method for preparing the display substrate, and a display apparatus.

### BACKGROUND

Micro organic light-emitting diode (Micro-OLED for short) is a micro display developed in recent years, and silicon-based OLED is a kind of micro display. The silicon-based OLED may not only realize active addressing of pixels, but also realize preparing a variety of functional circuits including timing control (TCON) circuit, over-current protection (OCP) circuit, or the like, on a silicon-based substrate, which is conducive to reducing system size and realizing light weight. Silicon-based OLEDs are manufactured using the mature Complementary Metal Oxide Semiconductor (CMOS) integrated circuit process. Due to their advantages such as small size, high Pixels Per Inch (PPI), and high refresh rate, they are widely used in the near-to-eye display field of Virtual Reality (VR) or Augmented Reality (AR).

### SUMMARY

The following is a summary of subject matter described in the present disclosure in detail. This summary is not intended to limit the protection scope of claims.

According to a first aspect, the present disclosure provides a display substrate, the display substrate includes: a base substrate, and a pixel definition layer and a first electrode which are arranged on the base substrate, the pixel definition layer includes an opening, a sidewall of the first electrode is stepped, and the opening exposes the first electrode;
the pixel definition layer at least covers a portion of the sidewall of the first electrode, an orthographic projection of a surface of the first electrode away from the base substrate on the base substrate is within an orthographic projection of the opening on the base substrate.

In an exemplary implementation, the first electrode includes a first structure and a second structure, the first structure is located on a side of the second structure away from the base substrate;
an orthographic projection of a surface of the second structure away from the base substrate on the base substrate covers an orthographic projection of the first structure on the base substrate, and a thickness of the second structure is greater than a thickness of the first structure;
a sidewall of the second structure is stepped.

In an exemplary implementation, the second structure includes: a first sub-layer, a second sub-layer, and a third sub-layer sequentially stacked on the base substrate; a thickness of the second sub-layer is greater than a thickness of the first sub-layer and is greater than a thickness of the third sub-layer;
an orthographic projection of a surface of the first sub-layer away from the base substrate on the base substrate covers an orthographic projection of the second sub-layer on the base substrate, an orthographic projection of a surface of the second sub-layer close to the base substrate on the base substrate covers an orthographic projection of a surface of the second sub-layer away from the base substrate on the base substrate, and the orthographic projection of the surface of the second sub-layer away from the base substrate on the base substrate covers an orthographic projection of the third sub-layer on the base substrate;
a sidewall of the second sub-layer is stepped;
the sidewall of the second sub-layer includes: a first inclined surface, a stepped surface, and a second inclined surface;
the stepped surface is parallel to the base substrate, the first inclined surface is located on a side of the stepped surface away from the base substrate, the second inclined surface is located on a side of the stepped surface close to the base substrate, and the stepped surface connects the first inclined surface and the second inclined surface.

In an exemplary implementation, the pixel definition layer includes: a first inorganic layer and a second inorganic layer stacked on the base substrate, the first inorganic layer is located on a side of the second inorganic layer close to the base substrate, and an orthographic projection of the second inorganic layer on the base substrate covers an orthographic projection of the first inorganic layer on the base substrate;
the first inorganic layer includes a first via, the second inorganic layer includes a second via, the opening includes the first via and the second via; wherein an orthographic projection of the first via on the base substrate covers an orthographic projection of the second via on the base substrate.

In an exemplary implementation, an orthographic projection of the first inorganic layer on the base substrate at least partially overlaps with an orthographic projection of the stepped surface of the second sub-layer on the base substrate and does not overlap with an orthographic projection of the first inclined surface of the second sub-layer on the base substrate.

In an exemplary implementation, centerlines of the first via and the second via coincide and are perpendicular to the base substrate;
a distance between a sidewall of the first inorganic layer close to the centerline of the first via and the centerline of the first via is greater than or equal to a distance between a sidewall of the second inorganic layer close to the centerline of the first via and the centerline of the first via.

In an exemplary implementation, when a distance between a sidewall of the first inorganic layer close to the first electrode and a centerline of the first electrode is greater than a distance between a sidewall of the second inorganic layer close to the first electrode and the centerline of the first electrode, an orthographic projection of the second inorganic layer on the base substrate further partially overlaps with an orthographic projection of the first inclined surface of the second sub-layer on the base substrate, and does not overlap with an orthographic projection of the first sub-layer on the base substrate.

In an exemplary implementation, the pixel definition layer further includes a third inorganic layer and a fourth inorganic layer, the third inorganic layer is located on a side of the first inorganic layer close to the base substrate, and the fourth inorganic layer is located on a side of the third inorganic layer close to the base substrate;
an orthographic projection of the third inorganic layer on the base substrate partially overlaps with an orthographic projection of the first structure on the base substrate; an orthographic projection of the fourth inorganic layer on the base substrate at least partially overlaps with an orthographic projection of the first sub-layer of the second structure on the base substrate, and the orthographic projections of the third inorganic layer and the fourth inorganic layer on the base substrate do not overlap with an orthographic projection of a surface of the first electrode away from the base substrate on the base substrate;
the third inorganic layer is provided with a third via, and the fourth inorganic layer is provided with a fourth via; the opening includes: the first via, the second via, the third via, and the fourth via;
an orthographic projection of the second via on the base substrate covers an orthographic projection of the third via on the base substrate and covers an orthographic projection of the fourth via on the base substrate.

In an exemplary implementation, the pixel definition layer further includes a first groove, a sidewall of the first groove has an undercut structure;
an orthographic projection of the first groove on the base substrate does not overlap with an orthographic projection of the first electrode on the base substrate.

In an exemplary implementation, the third inorganic layer includes: a bending portion and a planarization portion; the bending portion covers a sidewall of the first electrode and has a stepped shape, and the planarization portion is parallel to the base substrate;
the first inorganic layer further includes a fifth via, the second inorganic layer further includes a sixth via, the fifth via exposes the third inorganic layer, the first groove includes the fifth via and the sixth via, and a centerline of the fifth via is coincided with a centerline of the sixth via and is perpendicular to the base substrate;
a distance between a sidewall of the planarization portion away from the centerline of the fifth via and the centerline of the fifth via is greater than a distance between a sidewall of the fifth via and the centerline of the fifth via;
a surface of the first inorganic layer located on the planarization portion away from the base substrate is planar, and a surface of the second inorganic layer located on the planarization portion away from the base substrate is planar.

In an exemplary implementation, the display substrate further includes: a filling structure arranged within the first groove, a sidewall of the filling structure includes a plurality of second grooves;
a distance between a surface of the filling structure away from the base substrate and the base substrate is less than a minimum distance between a surface of the second inorganic layer close to the base substrate and the base substrate.

In an exemplary implementation, the filling structure includes: a plurality of first filling layers and a plurality of second filling layers which are stacked, one of the plurality of first filling layers is in contact with the third inorganic layer, and the plurality of first filling layers and the plurality of second filling layers are arranged to overlap;
a distance between a sidewall of the first filling layer and a centerline of the fifth via is less than a distance between a sidewall of the second filling layer and the centerline of the fifth via.

In an exemplary implementation, a thickness of the first inorganic layer is greater than a thickness of any one of the second inorganic layer, the third inorganic layer, and the fourth inorganic layer; a thickness of the second inorganic layer and the third inorganic layer is greater than a thickness of the fourth inorganic layer;
the first inorganic layer includes silicon nitride, the second inorganic layer and the fourth inorganic layer include silicon oxide, and the third inorganic layer includes aluminum oxide;
a thickness of the first filling layer is greater than or equal to a thickness of the second filling layer;
the first filling layer includes silicon nitride and the second filling layer includes silicon oxide.

In a second aspect, the present disclosure further provides a display apparatus, including the display substrate described above.

In a third aspect, the present disclosure further provides a preparation method of a display substrate, configured to prepare the display substrate described above. The method includes:
forming a first electrode on the base substrate, wherein a sidewall of the first electrode is stepped;
forming a pixel definition layer on the first electrode, wherein the pixel definition layer includes an opening, and the opening exposes the first electrode;
wherein the pixel definition layer at least covers a portion of the sidewall of the first electrode, and an orthographic projection of a surface of the first electrode away from the base substrate on the base substrate is within an orthographic projection of the opening on the base substrate;
forming the first electrode on the base substrate includes:
sequentially depositing a first sub-film, a second sub-film, a third sub-film, and a first structural film on the base substrate, patterning the first sub-film, the second sub-film, the third sub-film, and the first structural film by a patterning process to form a first original electrode having a slope-shaped sidewall;
patterning the first original electrode by a patterning process to form the first electrode;
forming a pixel definition layer on the first electrode includes:
sequentially depositing a fourth inorganic thin film and a third inorganic thin film on the first electrode, patterning the fourth inorganic thin film and the third inorganic thin film by a patterning process to form a fourth inorganic layer and a third inorganic layer of the pixel definition layer; sequentially depositing a first inorganic thin film and a second inorganic thin film on the third inorganic layer, patterning the first inorganic thin film and the second inorganic thin film by a patterning process to form a first inorganic layer and a second inorganic layer of the pixel definition layer; or
sequentially depositing a fourth inorganic thin film and a third inorganic thin film on the first electrode, patterning the fourth inorganic thin film and the third inorganic thin film by a patterning process to form a fourth inorganic layer and a third inorganic layer of the pixel definition layer; sequentially depositing a plurality of first filling films and a plurality of second filling films on the third inorganic layer, patterning the plurality of first filling films and the plurality of second filling films by a patterning process to form a filling structure including a plurality of first filling layers and a plurality of second filling layers; coating a protective film on the third inorganic layer, treating the protective film by a patterning process to form a protective layer surrounding the filling structure, the protective film includes a photoresist; coating a first inorganic thin film and a second inorganic thin film on the third inorganic layer, patterning the first inorganic thin film and the second inorganic thin film by a patterning process to form a first inorganic layer and a second inorganic layer of the pixel definition layer, and removing the protective layer.

Other aspects of the present disclosure may be comprehended after the drawings and the detailed descriptions are read and understood.

### BRIEF DESCRIPTION OF DRAWINGS

Accompany drawings are used to provide understanding of technical solutions of the present disclosure, and form a part of the specification. The accompany drawings and embodiments of the present disclosure are adopted to explain the technical solutions of the present disclosure, and do not form limitations on the technical solutions of the present disclosure.

FIG. 1 is a first schematic structural diagram of a display substrate according to an embodiment of the present disclosure.

FIG. 2 is a second schematic structural diagram of a display substrate according to an embodiment of the present disclosure.

FIG. 3 is a schematic diagram of a circuit principle according to an exemplary implementation.

FIG. 4 is a schematic diagram of an implementation of a circuit of a voltage control circuit and a pixel driving circuit.

FIG. 5 is a schematic diagram of a structure of an organic light emitting layer.

FIG. 6 is a first schematic diagram of a structure of a display substrate according to an exemplary implementation.

FIG. 7 is a second schematic diagram of a structure of a display substrate according to an exemplary implementation.

FIG. 8 is a schematic diagram after a base substrate is formed.

FIG. 9 is a schematic diagram after a first original electrode is formed.

FIG. 10 is a schematic diagram after a first electrode is formed.

FIG. 11 is a schematic diagram after the third inorganic layer is formed.

FIG. 12 is a schematic diagram of the display substrate provided in FIG. 1 after a second inorganic layer is formed.

FIG. 13 is a schematic diagram after the filling structure is formed.

FIG. 14 is a schematic diagram after the protective layer is formed.

FIG. 15 is a schematic diagram of the display substrate provided in FIG. 1 after a second inorganic layer is formed.

### DETAILED DESCRIPTION

To make objectives, technical solutions, and advantages of the present disclosure clearer, the embodiments of the present disclosure will be described in detail below with reference to the accompany drawings. It is to be noted that implementation modes may be implemented in multiple different forms. Those of ordinary skills in the art may easily understand such a fact that modes and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict. In order to keep following description of the embodiments of the present disclosure clear and concise, detailed description of part of known functions and known components are omitted in the present disclosure. The drawings of the embodiments of the present disclosure only involve structures involved in the embodiments of the present disclosure, and for other structures, reference may be made to conventional designs.

In the accompanying drawings, a size of each composition element, a thickness of a layer, or a region may be exaggerated sometimes for clarity. Therefore, an implementation of the present disclosure is not always limited to the size, and the shape and size of each component in the drawings do not reflect an actual scale. In addition, the accompanying drawings schematically illustrate ideal examples, and an implementation of the present disclosure is not limited to shapes, numerical values, or the like shown in the drawings.

Ordinal numerals “first”, “second”, “third”, etc., in the specification are set not to form limits in numbers but only to avoid confusion between composition elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements with reference to the accompanying drawings, not to indicate or imply that involved devices or elements are required to have specific orientations and be structured and operated with the specific orientations but only to easily and simply describe the present specification, and thus should not be understood as limitations on the present disclosure. The positional relationships between the constituent elements may be changed as appropriate according to a direction according to which each constituent element is described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be a fixed connection, or a detachable connection, or an integral connection; it may be a mechanical connection or an electrical connection; it may be a direct connection, or an indirect connection through middleware, or internal communication inside two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the specification.

In the specification, an “electrical connection” includes a case that constituent elements are connected together through an element with a certain electrical action. An “element with a certain electrical action” is not particularly limited as long as electrical signals between the connected constituent elements may be sent and received. Examples of the “element with a certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

In the specification, a “film” and a “layer” are interchangeable. For example, a “conductive layer” may be replaced with a “conductive film” sometimes. Similarly, an “insulation film” may be replaced with an “insulation layer” sometimes.

In the specification, “arranged in a same layer” described refers to a structure formed by patterning two (or more than two) structures through a same patterning process, and their materials may be the same or different. For example, materials of precursors for forming multiple structures arranged in a same layer are the same, and final materials may be the same or different.

A triangle, rectangle, trapezoid, pentagon, or hexagon, etc. in the specification is not strictly defined, and it may be an approximate triangle, rectangle, trapezoid, pentagon, or hexagon, etc. There may be some small deformations caused by tolerance, and there may be a chamfer, an arc edge, deformation, etc.

In the present disclosure, “about” refers to that a boundary is not defined so strictly and numerical values within a range of process and measurement errors are allowed.

An silicon-based OLED includes: a silicon-based backplane integrated with a driving circuit, and a pixel definition layer and an OLED light-emitting element array formed on the silicon-based backplane. Herein, the OLED light-emitting element array includes an anode, an organic OLED light-emitting layer and a cathode. Due to a large thickness of the anode, the segment difference of the pixel definition layer located on the anode is large, and when the cathode is subsequently formed, the cathode will be punctured, thus reducing the reliability of the display product.

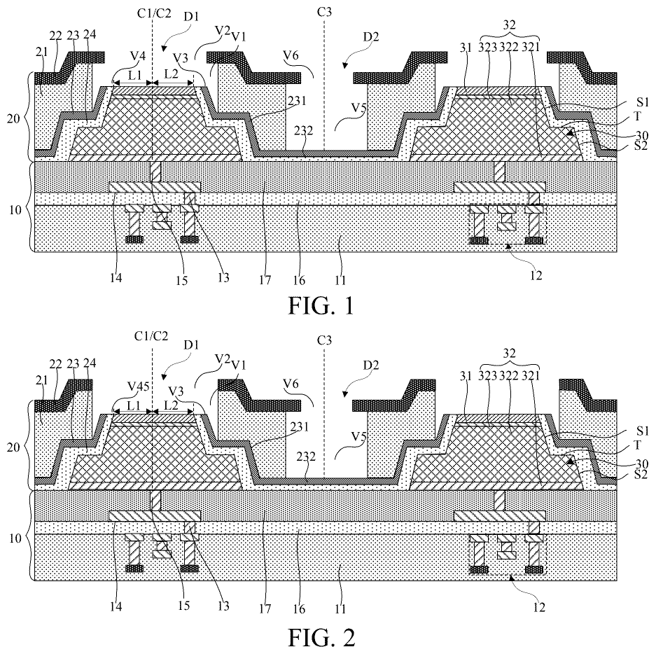

FIG. 1 is a first schematic structural diagram of a display substrate according to an embodiment of the present disclosure, and FIG. 2 is second a schematic structural diagram of a display substrate according to an embodiment of the present disclosure. As shown in FIGS. 1 and 2, a display substrate according to an embodiment of the present disclosure includes: a base substrate 10, and a pixel definition layer 20 and a first electrode 30 which are provided on the base substrate 10. The pixel definition layer 20 includes an opening D1, a sidewall of the first electrode 30 is stepped, and the opening D1 exposes the first electrode 30.

As shown in FIGS. 1 and 2, the pixel definition layer 20 at least covers a portion of the sidewall of the first electrode 30, an orthographic projection of the opening D1 on the base substrate 10 covers an orthographic projection of a surface of the first electrode 30 away from the base substrate 10 on the base substrate 10, for example, the orthographic projection of the surface of the first electrode 30 away from the base substrate 10 on the base substrate 10 is located within the orthographic projection of the opening D1 on the base substrate 10, and for example, a distance L1 between an edge of a surface of the first electrode 30 away from the base substrate 10 and a centerline C1 of the first electrode 30 is less than or equal to a minimum distance L2 between a sidewall of the opening D1 and the centerline C1 of the first electrode 30, the centerline C1 of the first electrode 30 is perpendicular to the base substrate 10.

In an exemplary implementation, the base substrate 10 may be a driving backplane.

In an exemplary implementation, the display substrate may further include an organic light emitting layer and a second electrode sequentially stacked on the pixel definition layer. The organic light emitting layer is located between the first electrode and the second electrode, and emits light under the joint action of the first electrode and the second electrode.

In the present disclosure, the distance L1 between an edge of a surface of the first electrode 30 away from the base substrate and a centerline C1 of the first electrode 30 is less than or equal to a minimum distance L2 between a sidewall of the opening D1 and the centerline C1 of the first electrode 30, that is, an orthographic projection of the pixel definition layer 20 on the base substrate does not overlap with an orthographic projection of a surface of the first electrode 30 away from the base substrate 10 on the base substrate, and the pixel definition layer 20 only covers a sidewall of the first electrode, but does not cover the surface of the first electrode 30 away from the substrate 10. FIG. 1 and FIG. 2 are illustrative in that the pixel definition layer completely covers the sidewall of the first electrode 30. In FIG. 1 and FIG. 2, the distance L1 between an edge of a surface of the first electrode 30 away from the base substrate and the centerline C1 of the first electrode 30 is equal to the minimum distance L2 between a sidewall of the opening D1 and the centerline C1 of the first electrode 30.

In the present disclosure, a segment difference of the pixel definition layer can be reduced by providing the sidewall of the first electrode in a stepped shape and providing an orthographic projection of a surface of the first electrode away from the base substrate on the base substrate within an orthographic projection of the opening on the base substrate, and subsequent piercing of the second electrode can be avoided.

In an exemplary implementation, as shown in FIGS. 1 and 2, the base substrate 10 may include a substrate 11, a transistor 12 provided in the substrate 11, and a first conductive post 13, a connection electrode 14, and a second conductive post 15 provided sequentially on the substrate 11. The first conductive post 13 is electrically connected to the transistor 12 and the connection electrode 14, respectively, and the second conductive post 15 is electrically connected to the connection electrode 14 and the first electrode 30, respectively.

In an exemplary implementation, as shown in FIGS. 1 and 2, the base substrate 10 may further include: a first insulating layer 16 located between the substrate 11 and the connection electrode 14, and a second insulating layer 17 located between the connection electrode 14 and the first electrode 30.

In an exemplary implementation, as shown in FIGS. 1 and 2, the first insulating layer 16 is provided with a via that exposes the transistor 12, and the first conductive post 13 is located within the via of the first insulating layer.

In an exemplary implementation, as shown in FIGS. 1 and 2, the second insulating layer 17 is provided with a via that exposes the connection electrode 14, and the second conductive post 15 is located within the via of the second insulating layer.

In an exemplary implementation, an active layer of the transistor 12 is arranged inside the substrate 11.

In an exemplary implementation, the transistor 12 may be a Metal Oxide Semiconductor (MOS).

In an exemplary implementation, the transistor may include: an active layer, a gate electrode, a source electrode, a drain electrode, and a gate connection electrode. Herein, the source electrode and the drain electrode are respectively connected to the active layer, and the gate connection electrode is connected to the gate electrode. The transistor may be in a bottom gate structure or may be in a top gate structure.

In an exemplary implementation, a preparation material of the active layer may include: a metal oxide.

In an exemplary implementation, a preparation material of the first insulating layer 16 and the second insulating layer 17 includes at least one of an organic material or an inorganic material, which may be, for example, silicon oxide (SiOx), silicon nitride (SiNx), or silicon oxide nitride (SiON). A structure of the first insulating layer 16 and the second insulating layer 17 may be a single-layer structure or a multi-layer composite structure.

In an exemplary implementation, a preparation material of the first conductive post 13 and the second conductive post 15 may be tungsten.

In an exemplary implementation, a preparation material of the connection electrode 14 includes a metal, for example, which may be silver or aluminum. A structure of the connecting electrode 14 may be a single-layer structure or a multi-layer composite structure.

In an exemplary implementation, the display substrate may include a pixel driving circuit, and the pixel driving circuit includes a plurality of transistors 12 located on the substrate 11, and the transistors may include at least one of a switching transistor, a driving transistor, a reset transistor, and a compensation transistor.

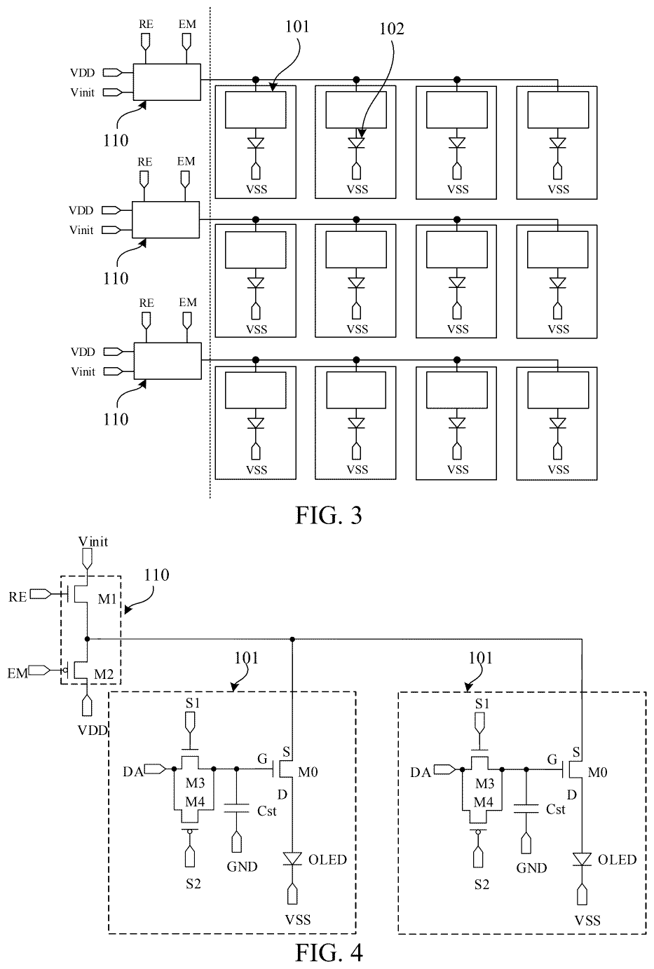

FIG. 3 is a schematic diagram of a circuit principle according to an exemplary implementation. As shown in FIG. 3, multiple sub-pixels in the display region are regularly arranged to form multiple display rows and multiple display columns. Each sub-pixel includes a pixel driving circuit 101, and a light emitting device 102 connected with the pixel driving circuit 101. The pixel driving circuit 101 at least includes a driving transistor. The control circuit at least includes a plurality of voltage control circuits 110, each of which is connected with multiple pixel driving circuits 101. For example, one voltage control circuit 110 is connected with pixel driving circuits 101 in one display row, first electrodes of driving transistors in the pixel driving circuits 101 of the display row are jointly connected to the voltage control circuit 110, a second electrode of each driving transistor is connected with an anode of the light emitting device 102 of the present sub-pixel, and a cathode of the light emitting device 102 is connected to an input end of a second power supply signal VSS. The voltage control circuit 110 is connected with an input end of a first power supply signal VDD, an input end of an initialization signal Vinit, an input end of a reset control signal RE, and an input end of a light emitting control signal EM, respectively. The voltage control circuit 110 is configured to output the initialization signal Vinit to the first electrode of the driving transistor in response to the reset control signal RE, to control the corresponding light emitting device 102 to reset. The voltage control circuit 110 is further configured to, in response to the light emission control signal EM, output the first power supply signal VDD to the first electrode of the driving transistor to drive the light emitting device 102 to emit light. By jointly connecting, by pixel driving circuits 101 in one display row to the voltage control circuit 110, the structure of the pixel driving circuit 101 can be simplified, and an occupied area of the pixel driving circuit 101 can be reduced, so that more pixel driving circuits 101 and light emitting devices 102 are arranged on the display substrate to realize high PPI display. The voltage control circuit 110 outputs the initialization signal Vinit to the first electrode of the driving transistor under the control of the reset control signal RE so as to control the corresponding light emitting device 102 to reset, which can avoid the influence of the voltage applied to the light emitting device 102 during the previous light emission on the next light emission, and can improve the image retention phenomenon.

In an exemplary implementation, one voltage control circuit 110 may be connected to pixel driving circuits 101 in two adjacent sub-pixels in a same display row, or may be connected to pixel driving circuits 101 in three or more sub-pixels in a same display row.

FIG. 4 is a schematic diagram of an implementation of a circuit of a voltage control circuit and a pixel driving circuit. As shown in FIG. 4, the light emitting device may include an OLED. An anode of the OLED is connected with a second electrode D of a driving transistor M0, and a cathode of the OLED is connected with the input end of the second power supply signal VSS.

In an exemplary implementation, a voltage of the second power supply signal VSS may be a negative voltage or a ground voltage VGND (generally 0V). Voltage of the initialization signal Vinit may be the ground voltage VGND.

In an exemplary implementation, the OLED may be a Micro-OLED or a Mini-OLED to facilitate realization of high PPI display.

In an exemplary implementation, the voltage control circuit 110 is connected with two pixel driving circuits 101 in a display row. The pixel driving circuit 101 includes a driving transistor M0, a third transistor M3, a fourth transistor M4 and a storage capacitor Cst, and the voltage control circuit 110 includes a first transistor M1 and a second transistor M2. The driving transistor M0, the first transistor M1, the second transistor M2, the third transistor M3 and the fourth transistor M4 are all transistors fabricated in the substrate.

As shown in FIG. 4, a control electrode of the first transistor M1 is connected to an input end of the reset control signal RE, and is configured to receive the reset control signal RE, a first electrode of the first transistor M1 is connected to an input end of the initialization signal Vinit and is configured to receive the initialization signal Vinit, and a second electrode of the first transistor M1 is connected to a first electrode S of the corresponding driving transistor M0 and a second electrode of the second transistor M2, respectively. A control electrode of the second transistor M2 is connected to the input end of the light emitting control signal EM and is configured to receive a light emitting control signal EM, a first electrode of the second transistor M2 is connected to the input end of the first power source signal VDD and is configured to receive a first power source signal VDD, and the second electrode of the second transistor M2 is connected to the first electrode S of the corresponding driving transistor M0 and the second electrode of the first transistor M1. In an exemplary implementation, the types of the first transistor M1 and the second transistor M2 may be different. For example, the first transistor M1 is an N-type transistor and the second transistor M2 is a P-type transistor, or the first transistor M1 is a P-type transistor and the second transistor M2 is an N-type transistor. In some possible implementations, the types of the first transistor M1 and the second transistor M2 may be same, which may be designed and determined according to an actual application environment.

As shown in FIG. 4, the pixel driving circuit 101 includes: a driving transistor M0, a third transistor M3, a fourth transistor M4, and a storage capacitor Cst. A control electrode G of the driving transistor M0 and the first electrode S of the driving transistor M0 are connected with the second electrode of the first transistor M1 and the second electrode of the second transistor M2, and a second electrode D of the driving transistor M0 is connected with the anode of the OLED. A control electrode of the third transistor M3 is connected to an input end of a first control electrode scan signal S1 and is configured to receive a first control electrode scan signal S1, a first electrode of the third transistor M3 is connected to an input end of a data signal DA and is configured to receive a data signal DA, and a second electrode of the third transistor M3 is connected to the control electrode G of the driving transistor M0. A control electrode of the fourth transistor M4 is connected to an input end of a second control electrode scan signal S2 and is configured to receive a second control electrode scan signal S2, a first electrode of the fourth transistor M4 is connected to the input end of the data signal DA and is configured to receive a data signal DA, and a second electrode of the fourth transistor M4 is connected to the control electrode G of the driving transistor M0. A first terminal of the storage capacitor Cst is connected with the control electrode G of the driving transistor M0, and a second terminal of the storage capacitor Cst is connected with the ground terminal GND. In an exemplary implementation, the driving transistor M0 may be an N-type transistor, and the type of the third transistor M3 may be different from that of the fourth transistor M4, for example, the third transistor M3 is an N-type transistor and the fourth transistor M4 is a P-type transistor. When the voltage of the data signal DA is a voltage corresponding to a high gray scale, by turning on the P-type fourth transistor M4 to transmit the data signal DA to the control electrode G of the driving transistor M0, the voltage of the data signal DA can be prevented from being affected, for example, by the threshold voltage of the N-type third transistor M3. When the voltage of the data signal DA is a voltage corresponding to a low gray scale, by turning on the N-type third transistor M3 to transmit the data signal DA to the control electrode G of the driving transistor M0, the voltage of the data signal DA can be prevented from being affected by the threshold voltage of the P-type fourth transistor M4. In this way, the voltage range input to the control electrode G of the driving transistor M0 can be increased.

In an exemplary implementation, the third transistor M3 is a P-type transistor, and the fourth transistor M4 is an N-type transistor.

In an exemplary implementation, the pixel driving circuit may be a 3T1C, 5T1C or 7T1C circuit structure, or may be a circuit structure with an internal compensation function or external compensation function.

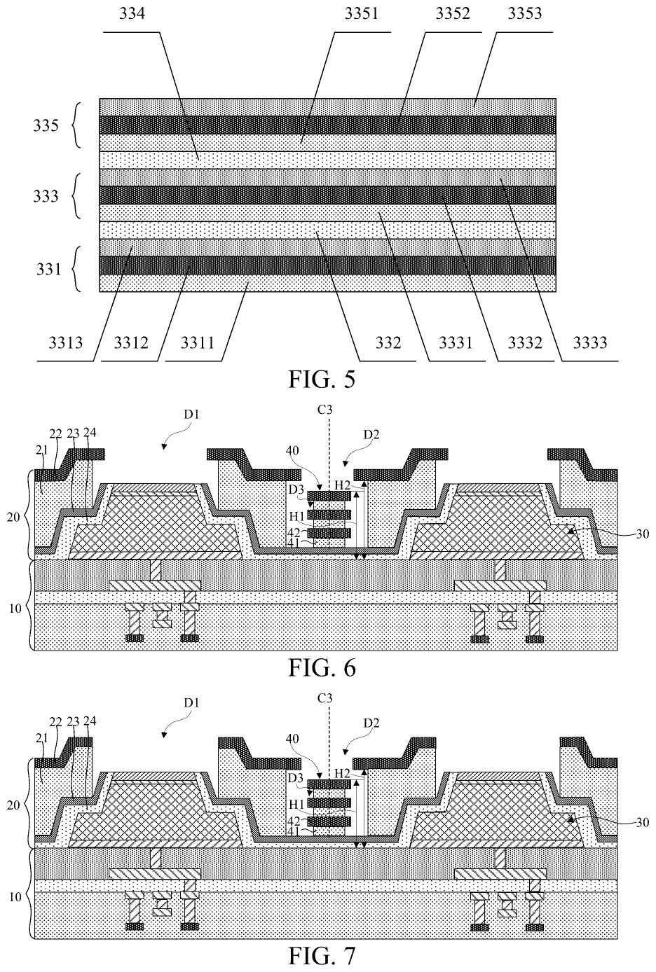

FIG. 5 is a schematic diagram of a structure of an organic light emitting layer. As shown in FIG. 5, the organic light emitting layer according to an exemplary embodiment includes a first light emitting sub-layer 331, a first charge generating layer 332, a second light emitting sub-layer 333, a second charge generating layer 334 and a third light emitting sub-layer 335 that are sequentially stacked between the first electrode and the second electrode.

As shown in FIG. 5, the first light emitting sub-layer 331 is configured to emit light of a first color, and includes a first hole transporting layer (HTL) 3311, a first emitting material layer (EML) 3312, and a first electron transporting layer (ETL) 3313 which are sequentially stacked. The second light emitting sub-layer 333 is configured to emit light of a second color, and includes a second hole transporting layer 3331, a second light emitting material layer 3332 and a second electron transporting layer 3333 which are sequentially stacked. The third light emitting sub-layer 335 is configured to emit light of a third color, and includes a third hole transporting layer 3351, a third light emitting material layer 3352 and a third electron transporting layer 3353 which are sequentially stacked. The first charge generating layer 332 is arranged between the first light emitting sub-layer 331 and the second light emitting sub-layer 333, and is configured to connect the two light emitting sub-layers in series to achieve carrier transfer. The second charge generating layer 334 is arranged between the second light emitting sub-layer 333 and the third light emitting sub-layer 335, and is configured to connect the two light emitting sub-layers in series to achieve carrier transfer. Since the organic light emitting layer includes a first emitting material layer emitting light of a first color, a second emitting material layer emitting light of a second color and a third light emitting material layer emitting light of a third color, thus light eventually emitted by the organic light emitting layer is mixed light. For example, it may be arranged that the first emitting material layer is a red light material layer emitting red light, the second emitting material layer is a green light material layer emitting green light, and the third emitting material layer is a blue light material layer emitting blue light, and thus the organic light emitting layer eventually emits white light.

In practice, the structure of the organic light emitting layer may be designed according to an actual need. In each light emitting sub-layer, in order to improve efficiency of injecting electrons and holes into the light emitting material layer, a hole injection layer and an electron injection layer may also be arranged. In order to simplify the structure of the organic light emitting layer, the first electron transporting layer 3313, the first charge generating layer 332 and the second hole transporting layer 3331 may be removed, that is, the second light emitting material layer 3332 may be arranged directly on the first light emitting material layer 3312.

In an exemplary implementation, the organic light emitting layer may adopt an organic light emitting layer emitting light of a first color and an organic light emitting layer emitting complementary light of the first color, and the two organic light emitting layers are sequentially stacked relative to the base substrate, thereby emitting white light as a whole.

In an exemplary implementation, an orthographic projection of the first electrode 30 on the base substrate 10 covers an orthographic projection of the organic light emitting layer on the base substrate 10, that is, a cross-sectional area of the first electrode 30 is greater than or equal to a cross-sectional area of the organic light emitting layer, so that the display brightness of the display substrate can be improved.

In an exemplary implementation, the second electrode may be a planar electrode.

In an exemplary implementation, the second electrode is a transmission electrode for transmitting light emitted by the organic light emitting layer.

In an exemplary implementation, a preparation material of the second electrode may be indium tin oxide or zinc tin oxide, or another transparent conductive material.

In an exemplary implementation, the display substrate may further include: a color film layer and an encapsulation layer located on a side of the second electrode away from the substrate.

In an exemplary implementation, the encapsulation layer may be a stacked structure and may include: a first inorganic encapsulation layer, a second inorganic encapsulation layer, and an organic encapsulation layer.

In an exemplary implementation, a preparation material of the first inorganic encapsulation layer may include silicon nitride. The first inorganic encapsulation layer may avoid damage to the light emitting structure layer when the second inorganic encapsulation layer is prepared. Since the first inorganic encapsulation layer has an inorganic characteristic, it not only has a good encapsulation characteristic, but also has good adhesion with the second electrode, which ensures encapsulation effect of the encapsulation layer.

In an exemplary implementation, a preparation material of the second inorganic encapsulation layer may include aluminum oxide. The second inorganic encapsulation layer may block water and oxygen from entering the light emitting structure layer, which can prolong the service life of the light emitting structure layer.

In an exemplary implementation, a preparation material of the third organic encapsulation layer may include parylene. Since the third organic encapsulation layer has an organic characteristic, it not only has a better organic encapsulation characteristic, but also has a better particle coating ability, which may well coat particles on a film layer and prevent the film layer from piercing. In addition, a material with an organic characteristic may well release a stress between inorganic layers, and avoid defects such as microcracks or peeling caused by a higher stress. The third organic encapsulation layer 43 also has a better flatness characteristic, which may provide a flatter base substrate for subsequent color filter layer preparation and prevent the color filter layer preparation process from damaging the second inorganic encapsulation layer.

In an exemplary implementation, the first inorganic encapsulation layer and the second inorganic encapsulation layer are formed using a deposition process; and a deposition density of the first inorganic encapsulation layer is smaller than a deposition density of the second inorganic encapsulation layer.

In an exemplary implementation, the color film layer realizes full-color display using a method of combining white light with a color film, and using the method of combining white light with a color film can realize a high resolution greater than 2000, which can meet the requirements of VR/AR.

In an exemplary implementation, the display substrate further includes: a planarization layer, a bonding layer, and a cover plate. The planarization layer is located on a side of the color film layer away from the base substrate. The bonding layer is located on a side of the planarization layer away from the base substrate, and the cover plate is located on a side of the bonding layer away from the base substrate.

In an exemplary implementation, the preparation material of the planarization layer may include parylene. The preparation material of the bonding layer may include silicon dioxide, and the bonding layer made of inorganic materials can better bond with the cover plate. The cover plate may be a glass cover plate.

In an exemplary implementation, the display substrate further includes a frame sealant. The cover plate is fixed with the base substrate through the frame sealant. Herein, the frame sealant is arranged between the base substrate and the cover plate, which can provide protection for blocking the invasion of water and oxygen, and greatly improve the service life of a silicon-based OLED display substrate. In another exemplary implementation, the frame sealant may be arranged on a side of the cover plate, peripheral sides of the cover plate and the base substrate are sealed by the frame sealant, and an end face on a side of the frame sealant away from the base substrate is located between a surface of the cover plate adjacent to the base substrate and a surface of the cover plate away from the base substrate. This arrangement both may ensure the sealing effect and may prevent the frame sealant from protruding above the cover plate, thereby avoiding an increase in the thickness of the display substrate.

In an exemplary implementation, as shown in FIGS. 1 and 2, the first electrode 30 may include a first structure 31 and a second structure 32, wherein the first structure 31 is located on a side of the second structure 32 away from the base substrate 10. The arrangement of the first structure 31 can improve the conductivity of the first electrode, the second structure 32 includes a metal material, and the arrangement of the second structure 32 can reflect light, thereby increasing the utilization rate of light, and improving the light emission performance of the display substrate.

In an exemplary implementation, as shown in FIGS. 1 and 2, an orthographic projection of a surface of the second structure 32 away from the base substrate 10 on the base substrate 10 covers an orthographic projection of the first structure 31 on the base substrate 10, i.e., a cross-sectional area of the second structure 32 is greater than a cross-sectional area of the first structure 31.

In an exemplary implementation, as shown in FIGS. 1 and 2, a thickness of the second structure 32 may be greater than a thickness of the first structure 31 in a direction perpendicular to the base substrate 10.

In an exemplary implementation, as shown in FIGS. 1 and 2, a sidewall of the second structure 32 is stepped and a sidewall of the first structure 31 is sloped.

In an exemplary implementation, as shown in FIGS. 1 and 2, an included angle between a sidewall of the first structure 31 and the base substrate 10 is an acute angle, which, for example, may be greater than or equal to 50 degrees, and less than 90 degrees.

In an exemplary implementation, the first structure 31 may include a transparent conductive material such as indium tin oxide or zinc tin oxide.

In an exemplary implementation, as shown in FIGS. 1 and 2, a shape of a longitudinal section of the first structure 31 may be rectangular or trapezoidal. FIGS. 1 and 2 are described in an example in which the shape of the longitudinal cross section of the first structure 31 is trapezoidal.

In an exemplary implementation, as shown in FIGS. 1 and 2, the second structure 32 may include a plurality of sub-layer structures, for example, include three sub-layer structures: a first sub-layer 321, a second sub-layer 322, and a third sub-layer 323 that are sequentially stacked on the base substrate 10.

In an exemplary implementation, as shown in FIGS. 1 and 2, a thickness of the second sub-layer 322 may be greater than a thickness of the first sub-layer 321 and greater than a thickness of the third sub-layer 323.

In an exemplary implementation, as shown in FIGS. 1 and 2, an orthographic projection of a surface of the first sub-layer 321 away from the base substrate 10 on the base substrate 10 covers an orthographic projection of the second sub-layer 322 on the base substrate 10, an orthographic projection of a surface of the second sub-layer 322 close to the base substrate 10 on the base substrate 10 covers an orthographic projection of a surface of the second sub-layer 322 away from the base substrate 10 on the base substrate 10, and the orthographic projection of the surface of the second sub-layer 322 away from the base substrate 10 on the base substrate 10 covers an orthographic projection of the third sub-layer 323 onto the base substrate 10, i.e., a cross-sectional area of the first sub-layer 321 is greater than a cross-sectional area of the second sub-layer 322, and the cross-sectional area of the second sub-layer 322 is greater than a cross-sectional area of the third sub-layer 323.

In an exemplary implementation, as shown in FIGS. 1 and 2, shapes of the longitudinal sections of the first sub-layer 321 and the third sub-layer 323 may be rectangular or trapezoidal.

In an exemplary implementation, as shown in FIGS. 1 and 2, a sidewall of the first sub-layer 321 and a sidewall of the third sub-layer 323 have slope shapes, and an included angle between the sidewall of the first sub-layer 321 and the base substrate 10 and an included angle between the sidewall of the third sub-layer 323 and the base substrate 10 are acute angles, which may be more than or equal to 50 degrees and less than 90 degrees, for example.

In an exemplary implementation, as shown in FIGS. 1 and 2, the included angle between the sidewall of the first sub-layer 321 and the base substrate 10 may be greater than or equal to the included angle between the sidewall of the third sub-layer 323 and the base substrate 10.

In an exemplary implementation, the first sub-layer 321 may include titanium, the second sub-layer 322 may include aluminum, and the third sub-layer 323 may include titanium.

In an exemplary implementation, as shown in FIGS. 1 and 2, a sidewall of the second sub-layer 322 is stepped, and the sidewall of the second sub-layer 322 includes a first inclined surface S1, a stepped surface T, and a second inclined surface S2. Herein, the stepped surface T is parallel to the base substrate 10, the first inclined surface S1 is located on a side of the stepped surface T away from the base substrate 10, the second inclined surface S2 is located on a side of the stepped surface T close to the base substrate 10, and the stepped surface T connects the first inclined surface S1 and the second inclined surface S2.

In an exemplary implementation, as shown in FIGS. 1 and 2, the pixel definition layer 20 may include a first inorganic layer 21 and a second inorganic layer 22 stacked on the base substrate 10, and the first inorganic layer 21 may be located on a side of the second inorganic layer 22 close to the base substrate 10. An orthographic projection of the second inorganic layer 22 on the base substrate 10 covers an orthographic projection of the first inorganic layer 21 on the base substrate 10.

In an exemplary implementation, as shown in FIGS. 1 and 2, the first inorganic layer 21 may include a first via V1, the second inorganic layer 22 may include a second via V2, and the opening D1 includes the first via V1 and the second via V2.

In an exemplary implementation, as shown in FIGS. 1 and 2, the sidewalls of the first via V1 and the second via V2 are perpendicular to the base substrate 10, and an orthographic projection of the first via V1 on the base substrate 10 covers an orthographic projection of the second via V2 on the base substrate 10. In the present disclosure, the orthographic projection of the first via V1 on the base substrate 10 covering the orthographic projection of the second via V2 on the base substrate 10 may include that a cross-sectional area of the first via V1 is greater than a cross-sectional area of the second via V2. At this time, a sidewall of the via combination of the first via V1 and the second via V2 is an undercut structure, which can make the light emitting structure layer break and cannot transmit the lateral leakage current, and can improve the reliability of the display substrate. Or, it may further include that the cross-sectional area of the first via V1 is equal to the cross-sectional area of the second via V2, the via combination of the first via V1 and the second via V2 forms a through hole with a flat sidewall.

In an exemplary implementation, as shown in FIGS. 1 and 2, an orthographic projection of the first inorganic layer 21 on the base substrate 10 at least partially overlaps with an orthographic projection of the stepped surface T of the second sub-layer 322 on the base substrate 10, and does not overlap with an orthographic projection of the first inclined surface S1 of the second sub-layer 322 on the base substrate 10, that is, the first inorganic layer 21 only partially covers the second sub-layer.

In an exemplary implementation, as shown in FIGS. 1 and 2, centerlines of the first via V1 and the second via V2 coincide with each other and are perpendicular to the base substrate 10. A centerline C2 of the first via V1 coincides with a centerline C1 of the first electrode 30, or may not coincide with the centerline C1. FIGS. 1 and 2 are described by taking the centerline C2 of the first via V1 coincide with the centerline C1 of the first electrode 30 as an example.

In an exemplary implementation, as shown in FIGS. 1 and 2, a distance between a sidewall of the first inorganic layer 21 close to the first electrode 30 and the centerline C1 of the first electrode 30 is greater than or equal to a distance between a sidewall of the second inorganic layer 22 close to the first electrode 30 and the centerline C1 of the first electrode 30. FIG. 1 is described by an example in which a distance between a sidewall of the first inorganic layer 21 close to the first electrode 30 and the centerline C1 of the first electrode 30 is greater than a distance between a sidewall of the second inorganic layer 22 close to the first electrode 30 and the centerline C1 of the first electrode 30, and FIG. 2 is described by an example in which a distance between a sidewall of the first inorganic layer 21 close to the first electrode 30 and the centerline C1 of the first electrode 30 is equal to a distance between a sidewall of the second inorganic layer 22 close to the first electrode 30 and the centerline C1 of the first electrode 30.

In an exemplary implementation, as shown in FIG. 1, when a distance between a sidewall of the first inorganic layer 21 close to the first electrode 30 and the centerline C1 of the first electrode 30 is greater than a distance between a sidewall of the second inorganic layer 22 close to the first electrode 30 and the centerline C1 of the first electrode 30, the orthographic projection of the second inorganic layer 22 on the base substrate 10 further partially overlaps with an orthographic projection portion of the first inclined surface S1 of the second sub-layer 322 on the base substrate 10, and does not overlap with an orthographic projection of the first sub-layer 321 on the base substrate 10.

In an exemplary implementation, as shown in FIGS. 1 and 2, the pixel definition layer 20 may further include a third inorganic layer 23 and a fourth inorganic layer 24. Herein, the third inorganic layer 23 may be located on a side of the first inorganic layer 21 close to the base substrate 10, and the fourth inorganic layer 24 may be located on a side of the third inorganic layer 23 close to the base substrate 10.

In an exemplary implementation, the fourth inorganic layer 24 covers a sidewall of the first electrode 30.

In an exemplary implementation, as shown in FIGS. 1 and 2, an orthographic projection of the third inorganic layer 23 on the base substrate 10 partially overlaps with an orthographic projection of the first structure 31 on the base substrate 10.

In an exemplary implementation, as shown in FIGS. 1 and 2, an orthographic projection of the fourth inorganic layer 24 on the base substrate 10 at least partially overlaps with an orthographic projection of the first sub-layer 321 of the second structure 32 on the base substrate 10.

In an exemplary implementation, as shown in FIGS. 1 and 2, orthographic projections of the third inorganic layer 23 and the fourth inorganic layer 24 on the base substrate 10 do not overlap with an orthographic projection of a surface of the first electrode 30 away from the base substrate 10 on the base substrate 10.

In an exemplary implementation, as shown in FIGS. 1 and 2, the third inorganic layer 23 and the fourth inorganic layer 24 completely cover the sidewall of the first electrode 30.

In the exemplary implementation, as shown in FIGS. 1 and 2, the third inorganic layer 23 is provided with a third via V3, and the fourth inorganic layer 24 is provided with a fourth via V4. Herein, the opening D1 may include a first via V1, a second via V2, a third via V3, and a fourth via V4.

In an exemplary implementation, as shown in FIGS. 1 and 2, an orthographic projection of the second via V2 on the base substrate 10 covers an orthographic projection of the third via V3 on the base substrate 10, and covers an orthographic projection of the fourth via V4 on the base substrate 10.

In an exemplary implementation, as shown in FIGS. 1 and 2, the pixel definition layer 20 further includes a first groove D2, and a sidewall of the first groove D2 has an undercut structure. In the present disclosure, by providing a first groove having an undercut structure, the organic light emitting layer can be broken at the first groove, and the transmission of lateral leakage current is avoided.

In an exemplary implementation, as shown in FIGS. 1 and 2, an orthographic projection of the first groove D2 on the base substrate 10 does not overlap with an orthographic projection of the first electrode 30 on the base substrate 10.

In an exemplary implementation, a cross section of the first groove may be any shape such as a square, a circle, or an ellipse, and the present disclosure does not limit on the shapes.

In an exemplary implementation, a surface of the first inorganic layer away from the substrate is planar, wherein the first inorganic layer is located on the planarization portion. A surface of the second inorganic layer away from the substrate is planar, wherein the second inorganic layer is located on the planarization portion. That is, the heights of undercut structures adjacent to the different first electrodes are the same, so that the display effect of the display substrate can be ensured and the reliability of the display substrate can be improved.

In an exemplary implementation, as shown in FIGS. 1 and 2, the third inorganic layer 23 includes: a bending portion 231 and a planarization portion 232. The bending portion 231 covers a sidewall of the first electrode 30 and has a stepped shape, and the planarization portion 232 is parallel to the base substrate 10.

In an exemplary implementation, as shown in FIGS. 1 and 2, the first inorganic layer 21 further includes a fifth via V5, the second inorganic layer 22 further includes a sixth via V6, the fifth via V5 exposes the third inorganic layer 23, and the first groove D2 includes a fifth via V5 and a sixth via V6.

In an exemplary implementation, as shown in FIGS. 1 and 2, a centerline of the fifth via V5 and a centerline of the sixth via V6 coincide with each other and are perpendicular to the base substrate 10.

In an exemplary implementation, as shown in FIGS. 1 and 2, a distance between a sidewall of the planarization portion 232 away from the centerline of the fifth via V5 and the centerline C3 of the fifth via V5 is greater than a distance between a sidewall of the fifth via V5 and the centerline C3 of the fifth via V5.

In an exemplary implementation, FIG. 6 is a first schematic diagram of a structure of a display substrate according to an exemplary implementation, and FIG. 7 is a second schematic diagram of a structure of a display substrate according to an exemplary implementation. FIG. 6 is described by an example in which a cross-sectional area of the first via is greater than a cross-sectional area of the second via, and FIG. 7 is described by an example in which the cross-sectional area of the first via is equal to the cross-sectional area of the second via. As shown in FIGS. 6 and 7, the display substrate may further include a filling structure 40 arranged in the first groove D2, and a sidewall of the filling structure 40 includes a plurality of second grooves D3.

In an exemplary implementation, as shown in FIGS. 6 and 7, a distance H1 between a surface of the filling structure 40 away from the base substrate 10 and the base substrate 10 is less than a minimum distance H2 between a surface of the second inorganic layer 22 close to the base substrate 10 and the base substrate 10.

In an exemplary implementation, as shown in FIGS. 6 and 7, the filling structure 40 may include: a plurality of first filling layers 41 and a plurality of second filling layers 42 which are stacked, one of the plurality of first filling layers 41 is in contact with the third inorganic layer 23, and the plurality of first filling layers 41 and the plurality of second filling layers 42 are arranged to overlap with each other.

In the exemplary implementation, as shown in FIGS. 6 and 7, numbers of the first filling layer 41 and the second filling layer 42 are equal. FIGS. 6 and 7 are described by an example in which the numbers of first filling layers 41 and second filling layers 42 are 3. The present disclosure does not make any limitation on this.

In an exemplary implementation, as shown in FIGS. 6 and 7, a distance between a sidewall of the first filling layer 41 and the centerline C3 of the fifth via V5 is smaller than a distance between a sidewall of the second filling layer 42 and the centerline C3 of the fifth via V5, i.e., a sidewall of the second groove D3 has an undercut structure. In the present disclosure, by providing a filling structure including an undercut structure, the organic light emitting layer can be broken at the first groove, and the transmission of lateral leakage current is avoided.

In an exemplary implementation, a preparation material of the first filling layer 41 may be the same as a preparation material of the first inorganic layer.

In an exemplary implementation, a preparation material of the second filling layer 42 may be the same as a preparation material of the second inorganic layer.

In an exemplary implementation, as shown in FIGS. 1, 2, 6, and 7, a thickness of the first inorganic layer 21 may be greater than a thickness of any one of the second inorganic layer 22, the third inorganic layer 23, and the fourth inorganic layer 24. The thickness of the second inorganic layer 22 and the third inorganic layer 23 may be greater than the thickness of the fourth inorganic layer 24.

In an exemplary implementation, the first inorganic layer 21 may include silicon nitride.

In an exemplary implementation, the second inorganic layer 22 and the fourth inorganic layer 24 may include silicon oxide.

In an exemplary implementation, the third inorganic layer 23 includes aluminum oxide.

In an exemplary implementation, as shown in FIGS. 6 and 7, a thickness of the first filling layer 41 may be greater than or equal to a thickness of the second filling layer 42.

In an exemplary implementation, the first filling layer 41 may include silicon nitride.

In an exemplary implementation, the second filling layer 42 may include silicon oxide.

Exemplary description is made below through a preparation process of a display substrate. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation, and chemical vapor deposition. The coating may be any one or more of spray coating, spin coating, and inkjet printing. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are arranged in a same layer” in the present disclosure means that A and B are formed simultaneously through a same patterning process, and a “thickness” of a film layer is a dimension of the film layer in a direction perpendicular to a display substrate. In an exemplary implementation mode of the present disclosure, “an orthographic projection of B is within a range of an orthographic projection of A” or “an orthographic projection of A contains an orthographic projection of B” refers to that a boundary of the orthographic projection of B falls within a range of a boundary of the orthographic projection of A, or the boundary of the orthographic projection of A coincides with the boundary of the orthographic projection of B.

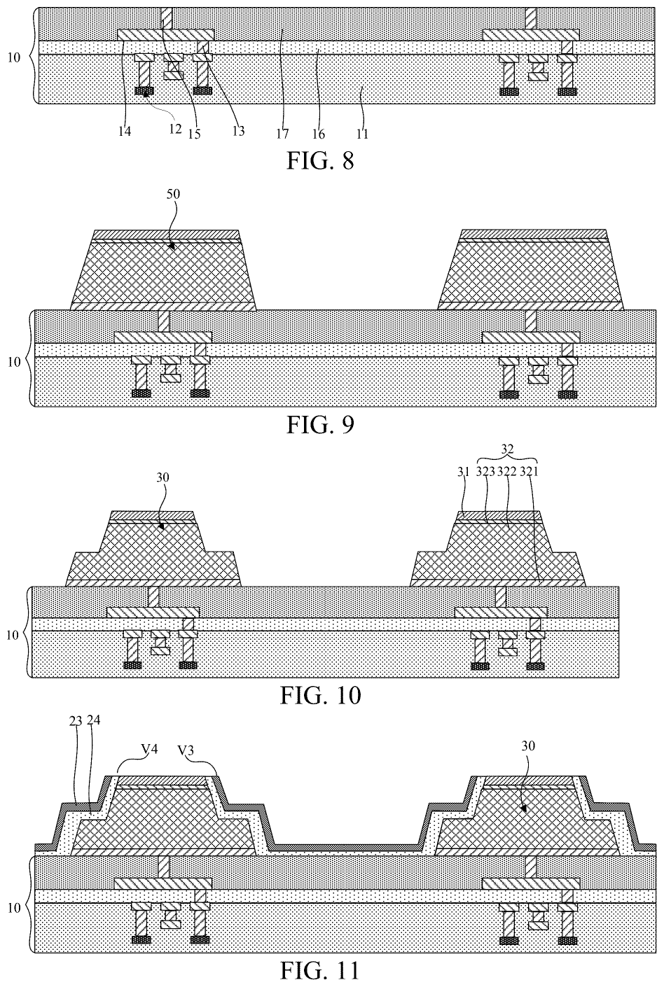

In an exemplary implementation, taking the display substrate provided in FIG. 1 as an example, a preparation process of the display substrate may include the following operations.
(1) Forming a base substrate 10. In an exemplary implementation, forming the base substrate 10 may include: providing a substrate 11, depositing a first insulating film on the substrate, patterning the first insulating film by a patterning process to form a first insulating layer 16, depositing a metal conductive film on the basis of formation of the aforementioned pattern, patterning the first conductive film by a patterning process to form a first conductive post 13, depositing a reflective film on the basis of formation of the aforementioned pattern, patterning the reflective film by a patterning process to form a connection electrode 14, depositing a second insulating film on the basis of formation of the aforementioned pattern, patterning the second insulating film by a patterning process to form second insulating film 17, depositing a second conductive film on the basis of formation of the aforementioned pattern, patterning the second conductive film by a patterning process to form a second conductive post 15, as shown in FIG. 8. FIG. 8 is a schematic diagram after the base substrate is formed.

In an exemplary implementation, the substrate 11 may include a transistor 12.

In an exemplary implementation, the first insulating layer 16 is provided with a via exposing a first electrode or a second electrode of the transistor. The first conductive post 13 is arranged in the via of the first insulating layer 16.

In an exemplary implementation, the second insulating layer 17 is provided with a via exposing the connection electrode 14. The second conductive post 15 is arranged in the via of the second insulating layer 17.
(2) Forming a first original electrode. In an exemplary implementation, forming the first original electrode includes sequentially depositing a first sub-film, a second sub-film, a third sub-film, and a first structural film on the basis of formation of the aforementioned pattern, and patterning the first sub-film, the second sub-film, the third sub-film, and the first structural film by a patterning process to form a first original electrode 50. FIG. 9 is a schematic diagram after a first original electrode is formed.

In an exemplary implementation, a sidewall of the first original electrode 50 is sloped.
(3) Forming a first electrode. In an exemplary implementation, forming the first electrode includes: patterning the first original electrode by a patterning process to form the first electrode 30. FIG. 10 is a schematic diagram after the first electrode is formed.

In an exemplary implementation, as shown in FIG. 10, the first electrode 30 includes a first structure 31 and a second structure 32 which are stacked. The second structure 32 includes a first sub-layer 321, a second sub-layer 322, and a third sub-layer 323.

In an exemplary implementation, as shown in FIG. 10, sidewalls of the first structure 31, the first sub-layer 321, and the third sub-layer 323 are sloped. A sidewall of the second sub-layer 322 is stepped.
(4) Forming a third inorganic layer. In an exemplary implementation, forming the third inorganic layer includes sequentially depositing a fourth inorganic thin film and a third inorganic thin film on the basis of formation of the aforementioned pattern, patterning the fourth inorganic thin film and the third inorganic thin film by a patterning process to form a fourth inorganic layer 24 and a third inorganic layer 23. FIG. 11 is a schematic diagram after the third inorganic layer is formed.

In the exemplary implementation, as shown in FIG. 11, the third inorganic layer 23 is provided with a third via V3 exposing the first electrode 30. The third via V3 exposes the upper surface of the first electrode 30 away from the base substrate 10.

In an exemplary implementation, as shown in FIG. 11, the fourth inorganic layer 24 is provided with a fourth via V4 exposing the first electrode 30. The fourth via V4 exposes the upper surface of the first electrode 30 away from the base substrate 10.

(5) Forming a second inorganic layer. In an exemplary implementation, forming the
second inorganic layer includes: sequentially depositing a first inorganic thin film and a second inorganic thin film on the basis of formation of the aforementioned pattern, patterning the first inorganic thin film and the second inorganic thin film by a patterning process to form a first inorganic layer 21 and a second inorganic layer 22. FIG. 12 is a schematic diagram of the display substrate provided in FIG. 1 after a second inorganic layer is formed.

In the exemplary implementation, as shown in FIG. 12, the first inorganic layer 21 is provided with a first via V1 and a fifth via V5. The first via V1 exposes an upper surface of the first electrode 30 away from the base substrate 10, and the fifth via V5 exposes the third inorganic layer.

In an exemplary implementation, as shown in FIG. 12, the second inorganic layer 22 is provided with a second via V2 and a sixth via V6. The second via V2 exposes the first via V1, and the sixth via V6 exposes the fifth via V5.

After forming the second inorganic layer, the method for preparing the display substrate may further include: coating an organic light emitting thin film on the basis of formation of the aforementioned pattern, patterning the organic light emitting thin film by a patterning process to form an organic light emitting layer, depositing a cathode thin film on the basis of formation of the aforementioned pattern, patterning the cathode thin film by a patterning process to form a second electrode.

The subsequent process may include: sequentially forming an encapsulation layer, a color film layer, a planarization layer, and a cover plate on the second electrode.

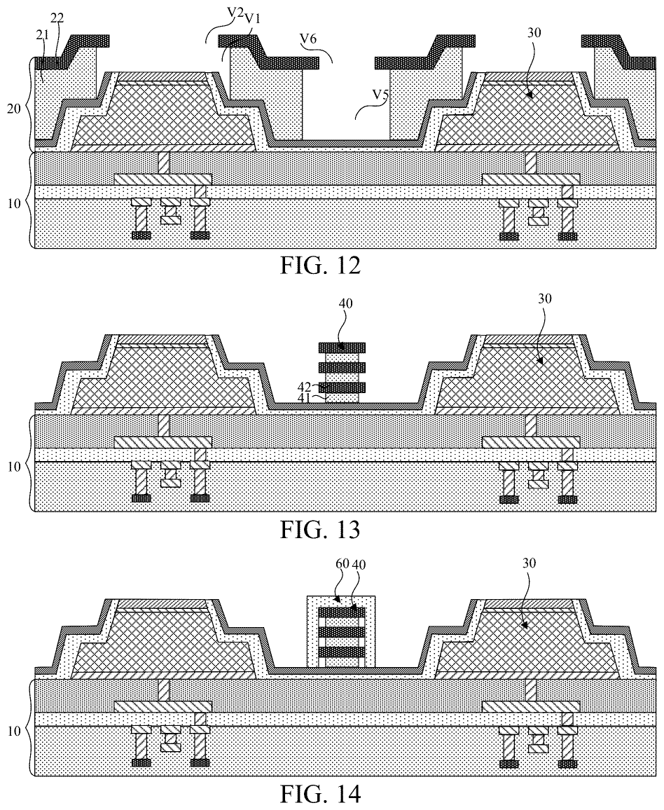

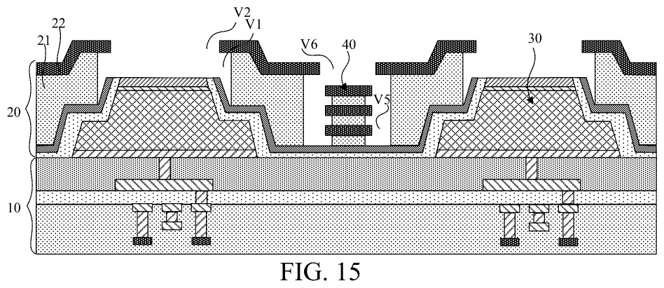

The display substrate provided in FIG. 6 is the same as the display substrate provided in FIG. 1 in the steps before forming the third inorganic layer and the steps after forming the second inorganic layer, except that the steps after forming the third inorganic layer, the steps before forming the third inorganic layer of the display substrate provided in FIG. 6 are not described again in detail. After forming the third inorganic layer, the method of preparing the display substrate may include:
(6) Forming a filling structure. In an exemplary implementation, forming the filling structure includes: depositing a plurality of first filling films and a plurality of second filling films on the basis of formation of the aforementioned pattern, patterning the plurality of first filling films and the plurality of second filling films by a patterning process, and forming a filling structure 40 including a plurality of first filling layers 41 and a plurality of second filling layers 42. FIG. 13 is a schematic diagram after the filling structure is formed.
(7) Forming a protective layer. In an exemplary implementation, forming the protective layer includes: coating a protective film on the basis of formation of the aforementioned pattern, and treating the protective film by a patterning process to form a protective layer 60 surrounding the filling structure. FIG. 14 is a schematic diagram after the protective layer is formed.

In an exemplary implementation, the protective film includes a photoresist.
(8) Forming a second inorganic layer. In an exemplary implementation, forming the second inorganic layer includes: sequentially depositing a first inorganic thin film and a second inorganic thin film on the basis of formation of the aforementioned pattern, patterning the first inorganic thin film and the second inorganic thin film by a patterning process, forming the first inorganic layer 21 and the second inorganic layer 22, and removing the protective layer to form the pixel definition layer 20. FIG. 15 is a schematic diagram of the display substrate provided in FIG. 1 after a second inorganic layer is formed.

In an exemplary implementation, the protective layer may be removed during a development process during the patterning process.

Embodiments of the present disclosure also provide a method of preparing a display substrate, configured to prepare a display substrate, the method includes:

In act 100, a first electrode is formed on a base substrate.

In an exemplary implementation, the sidewall of the first electrode is stepped.

In act 200, a pixel definition layer is formed on the first electrode.

In an exemplary implementation, the pixel definition layer includes an opening, the opening exposes a first electrode. The pixel definition layer covers at least a portion of a sidewall of the first electrode, an orthographic projection of a surface of the first electrode away from the base substrate on the base substrate is within an orthographic projection of the opening on the base substrate.

The display substrate is the display substrate according to any of the aforementioned embodiments, and has similar implementation principles and implementation effects, which will not be repeated here.

In an exemplary implementation, the act 100 may include:

Sequentially depositing a first sub-film, a second sub-film, a third sub-film and a first structural film on the base substrate, patterning the first sub-film, the second sub-film, the third sub-film and the first structural film by a patterning process to form a first original electrode having a slope-shaped sidewall;
patterning the first original electrode by a patterning process to form a first electrode.

In an exemplary implementation, the act 200 may include:

Sequentially depositing a fourth inorganic thin film and a third inorganic thin film on the first electrode, patterning the fourth inorganic thin film and the third inorganic thin film by a patterning process to form a fourth inorganic layer and a third inorganic layer of the pixel definition layer; sequentially depositing a first inorganic thin film and a second inorganic thin film on the third inorganic layer, and patterning the first inorganic thin film and the second inorganic thin film by a patterning process to form a first inorganic layer and a second inorganic layer of the pixel definition layer.

In an exemplary implementation, the act 200 may include:

Sequentially depositing a fourth inorganic thin film and a third inorganic thin film on the first electrode, patterning the fourth inorganic thin film and the third inorganic thin film by a patterning process to form a fourth inorganic layer and a third inorganic layer of a pixel definition layer; sequentially depositing a plurality of first filling films and a plurality of second filling films on the third inorganic layer, patterning the plurality of first filling films and the plurality of second filling films by a patterning process to form a filling structure including a plurality of first filling layers and a plurality of second filling layers; coating a protective film on the third inorganic layer, treating the protective film by a patterning process to form a protective layer surrounding the filling structure, wherein the protective film includes photoresist; coating a first inorganic thin film and a second inorganic thin film on the third inorganic layer, patterning the first inorganic thin film and the second inorganic thin film by a patterning process to form a first inorganic layer and a second inorganic layer of the pixel definition layer, and removing the protective layer.

An embodiment of the present disclosure further provides a display apparatus including a display substrate.

The display substrate is the display substrate according to any of the aforementioned embodiments, and has similar implementation principles and implementation effects, which will not be repeated here.

In an exemplary implementation, the display apparatus includes a VR device or an AR device.

The accompanying drawings of the present disclosure only involve the structures involved in the embodiments of the present disclosure, and other structures may refer to usual designs.

For the sake of clarity, a thickness and size of a layer or a micro structure are enlarged in the accompanying drawings used for describing the embodiments of the present disclosure. It may be understood that when an element such as a layer, film, region, or substrate is described as being “on” or “under” another element, the element may be “directly” located “on” or “under” the another element, or there may be an intermediate element.

Although the implementations of the present disclosure are disclosed above, the contents are only implementations used for ease of understanding of the present disclosure, but not intended to limit the present disclosure. Any of those skilled in the art of the present disclosure can make any modifications and variations in the implementation mode and details without departing from the spirit and scope of the present disclosure. However, the protection scope of the present disclosure should be subject to the scope defined by the appended claims.

1. A display substrate comprising: a base substrate, and a pixel definition layer and a first electrode which are arranged on the base substrate, wherein
the pixel definition layer comprises an opening, a sidewall of the first electrode is stepped, and the opening exposes the first electrode; and
the pixel definition layer at least covers a portion of the sidewall of the first electrode, and an orthographic projection of a surface of the first electrode away from the base substrate on the base substrate is within an orthographic projection of the opening on the base substrate.

2. The display substrate of claim 1, wherein
the first electrode comprises a first structure and a second structure, and the first structure is located on a side of the second structure away from the base substrate;
an orthographic projection of a surface of the second structure away from the base substrate on the base substrate covers an orthographic projection of the first structure on the base substrate, and a thickness of the second structure is greater than a thickness of the first structure; and
a sidewall of the second structure is stepped.

3. The display substrate of claim 2, wherein
the second structure comprises: a first sub-layer, a second sub-layer, and a third sub-layer sequentially stacked on the base substrate;
a thickness of the second sub-layer is greater than a thickness of the first sub-layer and greater than a thickness of the third sub-layer;
an orthographic projection of a surface of the first sub-layer away from the base substrate on the base substrate covers an orthographic projection of the second sub-layer on the base substrate, an orthographic projection of a surface of the second sub-layer close to the base substrate on the base substrate covers an orthographic projection of a surface of the second sub-layer away from the base substrate on the base substrate, and the orthographic projection of the surface of the second sub-layer away from the base substrate on the base substrate covers an orthographic projection of the third sub-layer on the base substrate;
a sidewall of the second sub-layer is stepped;
the sidewall of the second sub-layer comprises: a first inclined surface, a stepped surface, and a second inclined surface; and
the stepped surface is parallel to the base substrate, the first inclined surface is located on a side of the stepped surface away from the base substrate, the second inclined surface is located on a side of the stepped surface close to the base substrate, and the stepped surface connects the first inclined surface and the second inclined surface.

4. The display substrate of claim 3, wherein
the pixel definition layer comprises: a first inorganic layer and a second inorganic layer which are stacked on the base substrate, the first inorganic layer is located on a side of the second inorganic layer close to the base substrate, and an orthographic projection of the second inorganic layer on the base substrate covers an orthographic projection of the first inorganic layer on the base substrate; and
the first inorganic layer comprises a first via, the second inorganic layer comprises a second via, the opening comprises the first via and the second via; wherein an orthographic projection of the first via on the base substrate covers an orthographic projection of the second via on the base substrate.

5. The display substrate of claim 4, wherein an orthographic projection of the first inorganic layer on the base substrate at least partially overlaps with an orthographic projection of the stepped surface of the second sub-layer on the base substrate and does not overlap with an orthographic projection of the first inclined surface of the second sub-layer on the base substrate.

6. The display substrate of claim 5, wherein
centerlines of the first via and second via coincide and are perpendicular to the base substrate; and
a distance between a sidewall of the first inorganic layer close to the first electrode and a centerline of the first electrode is greater than or equal to a distance between a sidewall of the second inorganic layer close to the first electrode and a centerline of the first electrode.

7. The display substrate of claim 6, wherein when a distance between the sidewall of the first inorganic layer close to the first electrode and the centerline of the first electrode is greater than a distance between the sidewall of the second inorganic layer close to the first electrode and the centerline of the first electrode, an orthographic projection of the second inorganic layer on the base substrate further partially overlaps with an orthographic projection of the first inclined surface of the second sub-layer on the base substrate, and does not overlap with an orthographic projection of the first sub-layer on the base substrate.

8. The display substrate of claim 4, wherein
the pixel definition layer further comprises: a third inorganic layer and a fourth inorganic layer, the third inorganic layer is located on a side of the first inorganic layer close to the base substrate, and the fourth inorganic layer is located on a side of the third inorganic layer close to the base substrate;
an orthographic projection of the third inorganic layer on the base substrate partially overlaps with an orthographic projection of the first structure on the base substrate; an orthographic projection of the fourth inorganic layer on the base substrate at least partially overlaps with an orthographic projection of the first sub-layer of the second structure on the base substrate, and the orthographic projections of the third inorganic layer and the fourth inorganic layer on the base substrate do not overlap with an orthographic projection of a surface of the first electrode away from the base substrate on the base substrate;
the third inorganic layer is provided with a third via, and the fourth inorganic layer is provided with a fourth via; the opening comprises: the first via, the second via, the third via, and the fourth via; and
an orthographic projection of the second via on the base substrate covers an orthographic projection of the third via on the base substrate and covers an orthographic projection of the fourth via on the base substrate.

9. The display substrate of claim 8, wherein the pixel definition layer further comprises a first groove, a sidewall of the first groove has an undercut structure;
an orthographic projection of the first groove on the base substrate does not overlap with an orthographic projection of the first electrode on the base substrate.

10. The display substrate of claim 9, wherein
the third inorganic layer comprises a bending portion and a planarization portion; the bending portion covers the sidewall of the first electrode and has a stepped shape, and the planarization portion is parallel to the base substrate;
the first inorganic layer further comprises a fifth via, the second inorganic layer further comprises a sixth via, the fifth via exposes the third inorganic layer, the first groove comprises the fifth via and the sixth via, and a centerline of the fifth via is coincided with a centerline of the sixth via and is perpendicular to the base substrate;
a distance between a sidewall of the planarization portion away from the centerline of the fifth via and the centerline of the fifth via is greater than a distance between a sidewall of the fifth via and the centerline of the fifth via; and
a surface of the first inorganic layer located on the planarization portion away from the base substrate is planar, and a surface of the second inorganic layer located on the planarization portion away from the base substrate is planar.

11. The display substrate of claim 9, wherein
the display substrate further comprises: a filling structure arranged within the first groove, a sidewall of the filling structure comprises a plurality of second grooves; and
a distance between a surface of the filling structure away from the base substrate and the base substrate is less than a minimum distance between a surface of the second inorganic layer close to the base substrate and the base substrate.

12. The display substrate of claim 11, wherein
the filling structure comprises: a plurality of first filling layers and a plurality of second filling layers which are stacked, one of the plurality of first filling layers is in contact with the third inorganic layer, and the plurality of first filling layers and the plurality of second filling layers are arranged to overlap; and
a distance between a sidewall of the first filling layer and a centerline of the fifth via is less than a distance between a sidewall of the second filling layer and the centerline of the fifth via.

13. The display substrate of claim 12, wherein
a thickness of the first inorganic layer is greater than a thickness of any one of the second inorganic layer, the third inorganic layer, and the fourth inorganic layer; and a thickness of the second inorganic layer and a thickness of the third inorganic layer are greater than a thickness of the fourth inorganic layer;
the first inorganic layer comprises silicon nitride, the second inorganic layer and the fourth inorganic layer comprise silicon oxide, and the third inorganic layer comprises aluminum oxide;
a thickness of the first filling layer is greater than or equal to a thickness of the second filling layer; and
the first filling layer comprises silicon nitride and the second filling layer comprises silicon oxide.

14. A display apparatus, comprising: the display substrate of claim 1.

15. A preparation method for a display substrate, configured to prepare the display substrate of claim 1, the method comprising:
forming a first electrode on the base substrate, wherein a sidewall of the first electrode is stepped; and
forming a pixel definition layer on the first electrode, wherein the pixel definition layer comprises an opening, and the opening exposes the first electrode;
wherein the pixel definition layer at least covers a portion of the sidewall of the first electrode, and an orthographic projection of a surface of the first electrode away from the base substrate on the base substrate is within an orthographic projection of the opening on the base substrate;
wherein forming the first electrode on the base substrate comprises:
sequentially depositing a first sub-film, a second sub-film, a third sub-film, and a first structural film on the base substrate, patterning the first sub-film, the second sub-film, the third sub-film, and the first structural film by a patterning process to form a first original electrode having a slope-shaped sidewall; and
patterning the first original electrode by a patterning process to form the first electrode;
wherein forming a pixel definition layer on the first electrode comprises:
sequentially depositing a fourth inorganic thin film and a third inorganic thin film on the first electrode, patterning the fourth inorganic thin film and the third inorganic thin film by a patterning process to form a fourth inorganic layer and a third inorganic layer of the pixel definition layer; sequentially depositing a first inorganic thin film and a second inorganic thin film on the third inorganic layer, patterning the first inorganic thin film and the second inorganic thin film by a patterning process to form a first inorganic layer and a second inorganic layer of the pixel definition layer; or
sequentially depositing a fourth inorganic thin film and a third inorganic thin film on the first electrode, patterning the fourth inorganic thin film and the third inorganic thin film by a patterning process to form a fourth inorganic layer and a third inorganic layer of the pixel definition layer; sequentially depositing a plurality of first filling films and a plurality of second filling films on the third inorganic layer, patterning the plurality of first filling films and the plurality of second filling films by a patterning process to form a filling structure comprising a plurality of first filling layers and a plurality of second filling layers; coating a protective film on the third inorganic layer, treating the protective film by a patterning process to form a protective layer surrounding the filling structure, wherein the protective film comprises a photoresist; coating a first inorganic thin film and a second inorganic thin film on the third inorganic layer, patterning the first inorganic thin film and the second inorganic thin film by a patterning process to form a first inorganic layer and a second inorganic layer of the pixel definition layer, and removing the protective layer.

16. The display substrate of claim 5, wherein
the pixel definition layer further comprises: a third inorganic layer and a fourth inorganic layer, the third inorganic layer is located on a side of the first inorganic layer close to the base substrate, and the fourth inorganic layer is located on a side of the third inorganic layer close to the base substrate;
an orthographic projection of the third inorganic layer on the base substrate partially overlaps with an orthographic projection of the first structure on the base substrate; an orthographic projection of the fourth inorganic layer on the base substrate at least partially overlaps with an orthographic projection of the first sub-layer of the second structure on the base substrate, and the orthographic projections of the third inorganic layer and the fourth inorganic layer on the base substrate do not overlap with an orthographic projection of a surface of the first electrode away from the base substrate on the base substrate;
the third inorganic layer is provided with a third via, and the fourth inorganic layer is provided with a fourth via; the opening comprises: the first via, the second via, the third via, and the fourth via; and
an orthographic projection of the second via on the base substrate covers an orthographic projection of the third via on the base substrate and covers an orthographic projection of the fourth via on the base substrate.

17. The display substrate of claim 6, wherein
the pixel definition layer further comprises: a third inorganic layer and a fourth inorganic layer, the third inorganic layer is located on a side of the first inorganic layer close to the base substrate, and the fourth inorganic layer is located on a side of the third inorganic layer close to the base substrate;
an orthographic projection of the third inorganic layer on the base substrate partially overlaps with an orthographic projection of the first structure on the base substrate; an orthographic projection of the fourth inorganic layer on the base substrate at least partially overlaps with an orthographic projection of the first sub-layer of the second structure on the base substrate, and the orthographic projections of the third inorganic layer and the fourth inorganic layer on the base substrate do not overlap with an orthographic projection of a surface of the first electrode away from the base substrate on the base substrate;
the third inorganic layer is provided with a third via, and the fourth inorganic layer is provided with a fourth via; the opening comprises: the first via, the second via, the third via, and the fourth via; and
an orthographic projection of the second via on the base substrate covers an orthographic projection of the third via on the base substrate and covers an orthographic projection of the fourth via on the base substrate.

18. The display substrate of claim 7, wherein
the pixel definition layer further comprises: a third inorganic layer and a fourth inorganic layer, the third inorganic layer is located on a side of the first inorganic layer close to the base substrate, and the fourth inorganic layer is located on a side of the third inorganic layer close to the base substrate;
an orthographic projection of the third inorganic layer on the base substrate partially overlaps with an orthographic projection of the first structure on the base substrate; an orthographic projection of the fourth inorganic layer on the base substrate at least partially overlaps with an orthographic projection of the first sub-layer of the second structure on the base substrate, and the orthographic projections of the third inorganic layer and the fourth inorganic layer on the base substrate do not overlap with an orthographic projection of a surface of the first electrode away from the base substrate on the base substrate;
the third inorganic layer is provided with a third via, and the fourth inorganic layer is provided with a fourth via; the opening comprises: the first via, the second via, the third via, and the fourth via; and
an orthographic projection of the second via on the base substrate covers an orthographic projection of the third via on the base substrate and covers an orthographic projection of the fourth via on the base substrate.

19. The display substrate of claim 10, wherein
the display substrate further comprises: a filling structure arranged within the first groove, a sidewall of the filling structure comprises a plurality of second grooves; and
a distance between a surface of the filling structure away from the base substrate and the base substrate is less than a minimum distance between a surface of the second inorganic layer close to the base substrate and the base substrate.

20. A display apparatus, comprising: the display substrate of claim 2.
